(19) United States
(12) Patent Application Publication
(10) Pub. No.: US 2007/0108993 A1
(43) Pub. Date: May 17, 2007

(54) Virtual feel capaciflectors

(75) Inventor: John M. Vranish, Crofton, MD (US)

Correspondence Address: NASA GODDARD SPACE FLIGHT CENTER, 8800 GREENBELT ROAD, MAIL CODE 140.1, GREENBELT, MD, 20771, US

(73) Assignee: U.S.A as represented by the Administrator of the National Aeronautics and Space Administration

(21) Appl. No.: 11/250,701

(22) Filed: Sep. 30, 2005

(51) Int. Cl. G01R 27/26

(52) U.S. Cl. 324/662

(57) ABSTRACT

A capacitive proximity sensing device that uses Capaciflector electrodes to simulate human feel. A single contact surface of arbitrary shape functions as a single Capaciflector electrode, which can sense proximal or near contact with another surface at any point on the Capaciflector electrode surface. Sensing closer or further proximity between the contact surfaces corresponds to sensing physical contact between surfaces. The closer proximity is analogous to more applied force at the point of physical contact and further proximity is analogous to less applied force at the point of physical contact. “Virtual Feel” is performed by moving along a preferred direction while adjusting the tool to minimize proximity to side contacts.

### CROSS REFERENCE TO RELATED PATENTS

The present invention is related to inventions shown and described in:
U.S. Pat. No. Re. 36,772, entitled, “Driven Shielding Capacitive Proximity Sensor”, filed on Nov. 6, 1996; and,
U.S. Pat. No. 5,539,292, entitled “Capaciflector Guided Mechanisms”, filed on Nov. 28, 1994.

The above-noted related patents are assigned to the assignee of the present invention. These related patents are herein incorporated by reference.

### ORIGIN OF THE INVENTION

The invention described herein was made by employees of the United States Government, and may be manufactured and used by or for the Government for governmental purposes without the payment of any royalties thereon or therefor.

### BACKGROUND OF THE INVENTION

1. Field of the Invention

The invention relates generally to capacitive proximity sensing devices. More particularly, the present invention relates to a precision alignment and positioning capacitive proximity sensor.

2. Background Description

Capacitive proximity sensors are generally known. Capaciflector technology uses a capacitive proximity sensing element backed by a reflector driven at the same voltage and in phase with the sensing element. The reflector is used to reflect electrical field lines from the sensor away from a ground plane and towards an object being sensed. Capaciflector technology has many applications including precision robotic manipulation. Typically a robot, using some combination of camera, machine vision with feature recognition, pre-programmed prior knowledge and/or operator supervision, brings a tool near a fastener. The vision system positions and aligns the tool over the fastener and moves the tool down to contact the fastener. At some point, the tool obscures fastener view and tool motion continues to contact based on a computer trajectory. At contact there are inevitable positional uncertainties and misalignments between tool and fastener. Thus, mechanical guides are present to correct such errors. But, these corrections often introduce forces back into the robot system. For this reason, mechanical compliance is added to the robot system to permit the adjustment motion to occur and to reduce the forces generated in the process. The robot simultaneously may rotate the tool to the proper position. The tool is then pushed down onto the fastener. The rotation will enable tool and fastener to align. Light pressure may drive the aligned tool down to complete seating between tool and fastener. In robotic aerospace applications, a force torque sensor on the robot wrist provides a sense of feel and guides the robot movement in relieving stress during seating. Once seating is complete, the robot removes the fastener.

In current alignment or positioning devices, misalignments at contact can be greater than the mechanical capture range of guides, which may cause the assembly process to fail. Further, mechanical guides may be too large so as to be certain mechanical capture occurs. In addition, mechanical compliance in the robot arm/end-effector wrist may become too large and its behavior too uncertain. This can degrade successful task completion and cause precision alignment or positioning to fail. The energy stored in the robot arm/end-effector, while correcting misalignments, can release suddenly as a spring to disrupt control of an assembly process. And, in many cases, friction, generated by the mechanical guides during assembly/disassembly, detract from smooth and precise assembly/disassembly. Existing Capaciflector technology, “Capaciflector Guided Mechanisms” uses several sensors in an array attached to a tool. The use of several sensors may complicate construction and adds multiple electric lines to service the sensor electrodes. This can be difficult to manage, particularly when changing from one tool to another. Such an arrangement also complicates the ability of the tool to withstand high torque and stress without damage to the sensors.

### SUMMARY OF THE INVENTION

The present invention is directed to an improved capacitive proximity sensor that is particularly suited for precision alignment and positioning of a robotic arm or end-effector.

Accordingly, it is desired that the present invention provide a capacitive proximity sensor that is capable of facilitating the precise manipulation of a robot arm or end effector.

It is further desired that the present invention provide a capacitive proximity sensor that uses a minimum number of sensors and a minimum number of input/output leads.

In addition, it is desired that the present invention provide a capacitive proximity sensor that can manipulate a tool to seat over a mating fastener without contact.

In one embodiment of the present invention “Virtual Feel” Capaciflectors typically comprise two (2) mechanical components, one being manipulated by a robot type device to mate with another. A socket wrench being assembled over a hex bolt and an Allen wrench being inserted into a socket head screw are representative examples of Virtual Feel applications. Virtual Feel may be used in precision positioning and alignment during an assembly process to ensure proper mating and to prevent jamming. When the mechanical component being manipulated by the robot is also an electrically excited Capaciflector electrode and the mechanical component to which it is being mated is electrically conductive and grounded, intimate proximity between the two can be sensed prior to contact, thus non-contact virtual feel can be used in place of actual touch to perform sensory interactive precision assembly. In another embodiment, a Capaciflector socket wrench comprises an inner combination mechanical socket head wrench/Capaciflector-driven electrode (sensor #1), an outer combination mechanical jacket/Capaciflector-driven electrode (sensor #2), and an electrical insulator film layer separating the two (2) sensors. The inner and outer mechanical components/sensors may be arranged at the top of the wrench so as to interface with a robot chuck such that the wrench may be mechanically secured and independent electrical signals can pass from a robot controller to each of the sensors.

“Virtual Feel” Capaciflector tools may be configured so that each tool's contact surface also serves as a Capaciflector electrode. In this configuration a single contact surface of arbitrary shape can also function as a single Capaciflector electrode, which can sense proximal or near contact with another surface at any point on the Capaciflector electrode surface. In one embodiment, sensing closer or further proximity between the contact surfaces corresponds to sensing physical contact between surfaces wherein closer proximity is analogous to more applied force at the point of physical contact and further proximity is analogous to less applied force at the point of physical contact. While the sensor responses are similar in each case, physical contact is associated with actual feel and proximal variations may be associated with virtual feel. In another embodiment, precision positioning and alignment techniques are typically performed by moving along a preferred direction while adjusting the tool to minimize side loads and friction. Virtual Feel may be performed by moving along a preferred direction while adjusting the tool to minimize proximity to side contacts

### BRIEF DESCRIPTION OF THE DRAWINGS

FIG. 1 is a cross sectional side view of a socket wrench taken along lines B-B of FIG. 2 positioned over a bolt prior to engagement therewith in accordance with an embodiment of the present invention.

FIG. 2 is a top view of FIG. 1.

FIG. 3 is a cross-sectional side view showing an Allen-wrench positioned over a nut prior to engagement therewith in accordance with an embodiment of the present invention.

FIGS. 4a and 4b demonstrate the basic geometry of conductive plates moving in pure translation in accordance with an embodiment of the present invention.

FIG. 5a demonstrates the charge distribution of the conductive plate of FIG. 4a.

FIG. 5b demonstrates the charge distribution of the conductive plate of FIG. 4b.

FIG. 6a is a top view of FIG. 4a demonstrating the charge distribution of the conductive plate of FIG. 4a.

FIG. 6b is a top view of FIG. 4b demonstrating the charge distribution of the

FIG. 7a demonstrates the basic geometry of a conductive plate rotating about the plate bottom center in accordance with an embodiment of the present invention.

FIG. 7b demonstrates the basic geometry of a conductive plate rotating about the plate center in accordance with an embodiment of the present invention r.

FIG. 8a demonstrates the charge distribution of the conductive plate of FIG. 7a.

FIG. 8b demonstrates the charge distribution of the conductive plate of FIG. 7b

FIG. 9 is the conductive plate of FIG. 8a rotated θ degrees and demonstrating the charge distribution.

FIG. 10a demonstrates the charge distribution of a centered circular plate in accordance with an embodiment of the present invention.

FIG. 10b demonstrates the charge distribution of an off-center circular plate in accordance with an embodiment of the present invention.

FIG. 11a demonstrates the charge distribution of a centered hexagonal plate in accordance with an embodiment of the present invention.

FIG. 11b demonstrates the charge distribution of an off-center hexagonal plate in accordance with an embodiment of the present invention.

FIG. 11c is the conductive plate of FIG. 11a rotated θ degrees and demonstrating the charge distribution.

FIG. 12a demonstrates the charge distribution of a centered asymmetric object in accordance with an embodiment of the present invention.

FIG. 12b demonstrates the charge distribution of an off-centered asymmetric object in accordance with an embodiment of the present invention.

FIG. 12c is the asymmetric object of FIG. 12a rotated θ degrees and demonstrating the charge distribution.

FIG. 13 demonstrates the clocking alignment of the socket wrench of FIG. 1.

### DETAILED DESCRIPTION

Energy (electric, magnetic, thermal) may transfer from one object to another. When an energy transfer takes place, it inherently seeks the path of least resistance/impedance. Thus, energy typically moves along each object surface to gather at the point(s) nearest contact and, thereby, anticipates contact. Also, the energy transfer typically increases as the objects come closer to contact. By configuring a system such that a tool's mechanical contact surfaces also serve to transfer sensing energy (capacitance), pre-contact sensing, without blind spots, the concept of virtual feel may be introduced. Therefore, a single sensor reading from the surface of an object can sense, guide, precisely position and align two mating members in six (6) degrees-of-freedom (6 DOF) in a manner analogous to human feel, without actual contact, ergo, virtual feel.

In the one embodiment, two electrically conductive capacitor electrodes may be constructed such that one can coaxially fit inside the other with equal separation between them in all directions. One electrode can be energized with an electrical ac potential and the other electrically grounded to form a capacitor with displacement current passing between the two electrodes and electric charge pairs being distributed over their mutually proximal electrode surfaces. Displacement current and electrode charge pairs change (both in amount and in location) when one or more of the electrodes is moved. The closer the electrodes at any point, the greater the displacement current and increasingly so right up to contact. Surprise (dead zone) contacts are prevented. The change in displacement current and its rate of change can be measured as can the amount and direction of electrode movement. Cause and effect relationships between electrode movement (amount and direction) and displacement current change and rate of change can be related to precisely guide the removal from or insertion of one electrode inside the other in a non-contact manner, even with small separation. This non-contact “Virtual Feel” process of using electrical signals from displacement current rising and falling with electrode small gap separation changes may be analogous to “real feel” using electrical signals from actual contact pressure, force or torque.

Electric charge on the electrode/contact surface typically changes, in reaction to changes in the distance between the electrode contact surface and the surface of some object. Adjustments in the movement of the electrode contact surface may allow a single Capaciflector electrode to provide 6 DOF sensing information because the electrode contact surface and the single Capaciflector electrode are one in the same. As the contact surface is adjusted in one direction, electric charge may move along the contact surface to collect and increase around the point of nearest contact and net displacement current between the proximal contact surfaces may increase. The point of nearest contact may correspond to the actual point of contact, if one were using actual feel. The sensor electronics can report this as an increase in electrical signal (or virtual force). When the electrode contact surface is adjusted in the opposite direction to relieve this “virtual force”, the charge (and displacement current) can first decrease and then increase and redistribute to the new point of nearest contact. This, again, corresponds to the new, actual contact point, if one were using actual feel. The sensor electronics can report this sequence as first a decrease in virtual force, followed by an increase. In this manner, a single Capaciflector electrode can provide 6 DOF virtual force responses to wiggling motions. When a preferential direction of movement is included, non-contact “virtual feel” precision positioning and alignment can result.

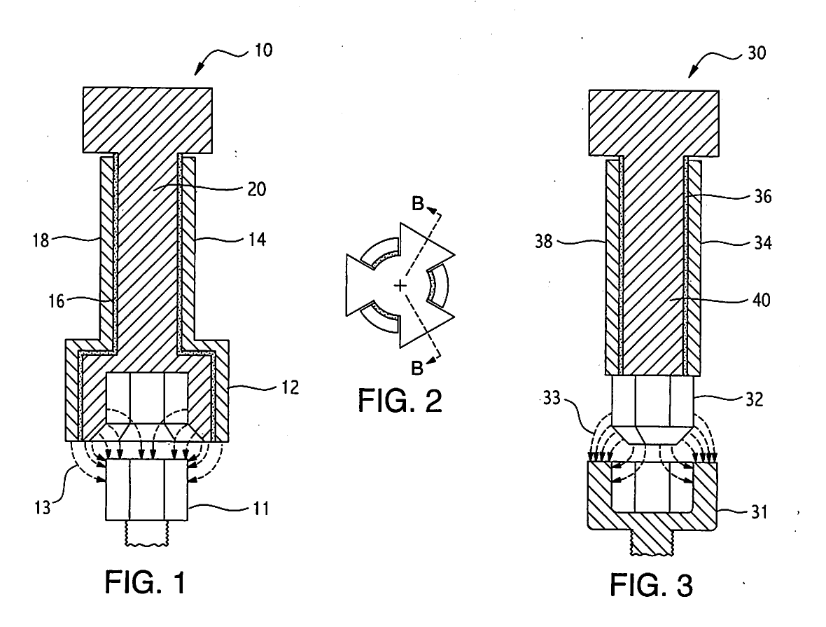

FIG. 1 shows an embodiment of an end-effector or socket wrench 10 that includes a socket head 12 and a neck 14 wherein socket head 12 is in close proximity to a nut 11. Socket head 12 is shown as a cross sectional view taken along lines B-B of FIG. 2. FIG. 2 is a top view of FIG. 1. Charge distribution lines 13 illustrate the path of capacitance as socket head 12 moves into close proximity to nut 11. Socket wrench 10 also may include an insulation film layer 16 which separates the outer shield/sensor 18 from the inner sensor 20. The outer shield/sensor 18 may shield the charge distribution from undesired objects. This may occur because the inner sensor 20 and outer sensor 18 function at the same electric potential (frequency, phase and amplitude).

FIG. 3 shows an embodiment of Allen wrench 30 that includes a head 32 and a neck 34 wherein head 32 is in close proximity to a nut 31. Charge distribution lines 33 illustrate the path of capacitance as head 32 moves into close proximity to nut 31. Allen wrench 30 also may include an insulation film layer 36 which separates the outer shield/sensor 38 from the inner sensor 40. The outer shield/sensor 38 can allow the tool to discriminate or shield the charge distribution from undesired objects. Sensors 38 and 40 may be made of a load bearing electrically conductive material.

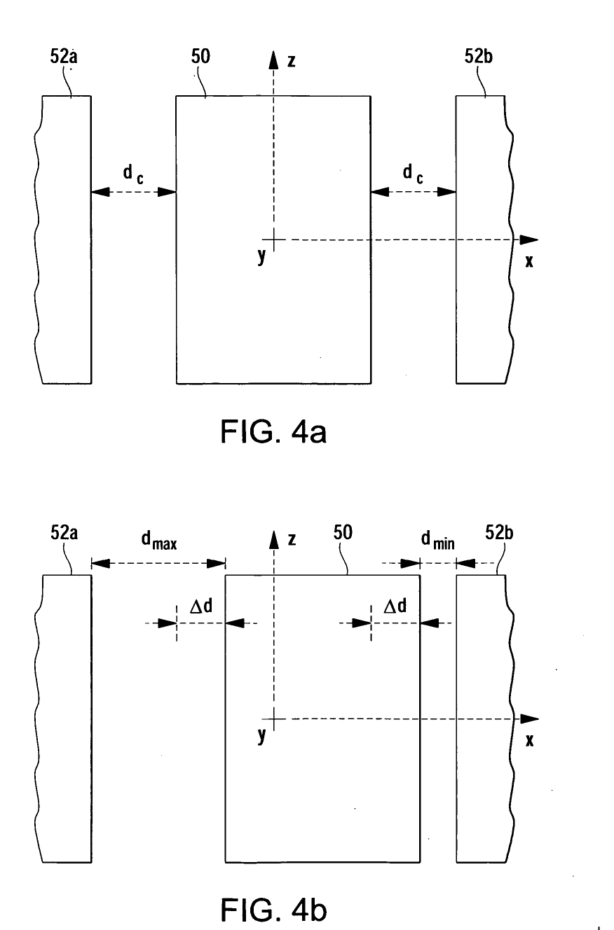

FIGS. 4a and 4b are simple geometric illustrations of the basic concept of virtual feel. FIG. 4a shows an embodiment of a Capaciflector electrode illustrated as plate 50 located between two plates 52a and 52b which represent ground. Plate 50 may be the same distance d_{c} from both plates 52a and 52b and all of the plates may be parallel and lie in the same plane defined by x-y coordinate axis shown on plate 50.

The basic capacitance equation for a parallel plate capacitor is defined as:

$$C = \frac{ɛ A}{d} \qquad ( 1 )$$

where
A=area of plate,
d=distance between plate and ground,

Thus, when a plate is center located between two (2) parallel plates as shown in FIG. 4a, we have:

$${C}_{C} = \frac{ɛ A}{{d}_{C}} + \frac{ɛ A}{{d}_{C}} = ɛ A ( \frac{2}{{d}_{C}} ) \qquad ( 2 )$$

Where d_{c} is the distance between plate 50 and the ground plates 52a and 52b when the plate 50 is centered. When the plate is moved a short distance (Δd) in the +x direction
we have:

$$\begin{matrix}\begin{matrix}{C}_{O C} = \frac{ɛ A}{{d}_{C} - Δ d} + \frac{ɛ A}{{d}_{C} + Δ d} \\ = ɛ A ( \frac{1}{{d}_{C} - Δ d} + \frac{1}{{d}_{C} + Δ d} ) \\ = ɛ A \frac{2 {d}_{C}}{{d}_{C} - {( Δ d )}^{2}}\end{matrix} & ( 3 ) \\ \frac{{C}_{O C}}{{C}_{C}} = \frac{ɛ A ( \frac{2 {d}_{C}}{{d}_{C}^{2} - {( Δ d )}^{2}} )}{ɛ A ( \frac{2}{{d}_{C}} )} = \frac{{d}_{C}^{2}}{{d}_{C}^{2} - ( Δ {d}^{2} )} > 1 & ( 4 )\end{matrix}$$

Thus, the minimum capacitance occurs when plate 50 is centered between parallel plates 52a and 52b. Whenever the plate is moved off center (either + or −), the capacitance increases. Therefore, as Δd approaches d_{c}, the capacitance becomes increasingly large. The closer plate 50 comes into contact with either of plates 52a or 52b, the stronger the capacitance and the stronger the sensor signal. The strength of the sensor signal is determined as follows:

Assuming a signal voltage of 1 volt when the plate is centered (this level is set reasonably high to yield maximum sensitivity) the circuitry (not shown) is set up so that the signal voltage increases as the capacitive coupling between the plate 50 and the parallel plates 52a or 52b increases. This concept is illustrated via equations (5) and (6),

$${V}_{C} = 1 volt \\ \frac{{V}_{O C}}{{V}_{C}} = \frac{{C}_{O C}}{{C}_{C}} \qquad ( 5 )$$

Assuming the electronics can discriminate a 30 millivolt change caused by increased displacement current.

Thus:

$$\frac{{V}_{O C}}{{V}_{C}} = \frac{{C}_{O C}}{{C}_{C}} = 1.03 = 1.03 - 1.03 {( \frac{Δ d}{{d}_{C}} )}^{2} = 1 \\ \sqrt{\frac{0.03}{1.03}} = \frac{Δ {d}_{C}}{{d}_{C}} = 1.70664 E - 1 \qquad ( 6 )$$

Thus, if d_{c}=0.005 in., Δd=8.5 E-4 in.

Then the precision is better than 0.001 in. for clearances of 0.010 in. total or 0.005 in. on each side of plate 50.

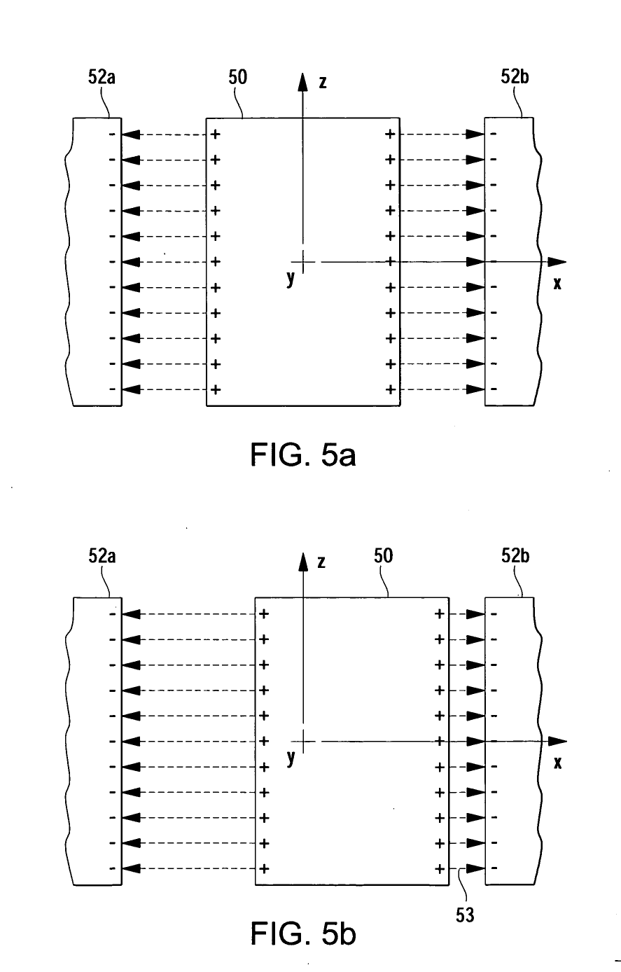

FIGS. 5a and 5b show one embodiment of parallel plates 50, 52a and 52b with their associated lines of capacitance 51. FIG. 5a shows a case of plate 50 being centered between parallel plates 52a and 52b. To illustrate the fact that this case represents minimum capacitance and thus minimal sensor signal, the charge distribution lines 51 are evenly distributed on both sides of plate 50. FIG. 5b represents a case where plate 50 moves in translation with respect to plates 52a and 52b. Thus, the effects of charge and electric field may be mathematically represented as follows:
Q=CV
Q=V(C₁+C₂) (7)

When the electrode plate 50 is centered between the parallel ground plates 52a and 52b:
C₁=C₂
Q=V2C₁ (8)

When the electrode plate 50 is translated across ½ the gap, the capacitance changes to:

$${C}_{1} \frac{2}{3}$$

across the gap that increases (for a net loss of ⅓ in 1) and:
C₁2 across the gap that decreases (for a net gain of 1 in 1). (9)

For a total of

$$Q = V {C}_{1} ( \frac{8}{3} ) \qquad ( 10 )$$

This presents a net relative charge and displacement current gain of:

$$Δ Q = V {C}_{1} ( \frac{2}{3} ) \qquad ( 11 )$$

The net relative charge can be measured by sensor circuitry (not shown). From the perspective of point pairs, the net relative gain represents the sum (or integral) of the net gains and losses of each point. When a point on a surface moves to close a gap, some point on the opposite surface moves an equal distance to open a gap. For this point pair, we get a net charge and displacement current increase; the larger the distance traveled and the greater the number of points (and area), the larger the increase. This relationship holds regardless of means of movement in perturbing the gaps (translation, rotation or some combination of the two). It also holds true regardless of the direction of movement. Whenever the perturbation moves from the center, which represents minimum capacitance, charge and displacement current show a net increase. FIG. 5b shows the charge distribution lines 53 which are closer together on the side approaching contact and further apart on the side that moves away from contact. This illustrates the fact that the capacitance increases on the side of plate 50 that approaches contact.

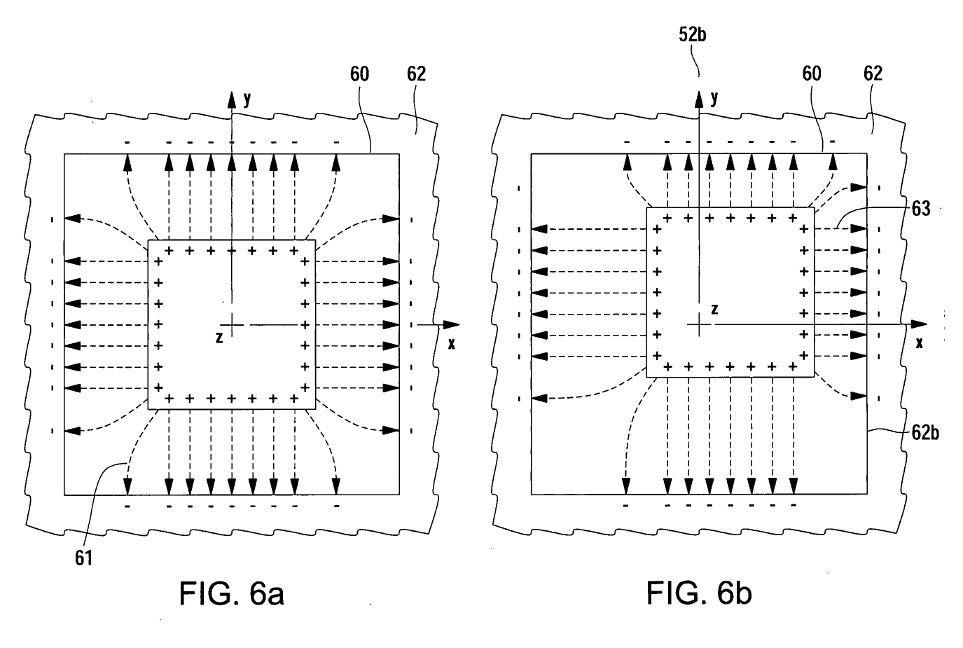

FIG. 6a shows an embodiment of an electrode plate 60 centered within a ground channel plate 62 and charge distribution lines 61. This illustration represents a rod inside an equal length channel. In this instance there is a net charge and displacement current increase when we depart from minimum capacitance center position in two dimensions.

FIG. 6b shows the increase is a superposition for the charge and capacitance for two (2) sets of orthogonal plates. The charge distribution lines 63 which are closer together on the sides approaching contact and further apart on the sides that moves away from contact illustrate the fact that capacitance increases as plate 60 approaches channel walls 62a and 62b.

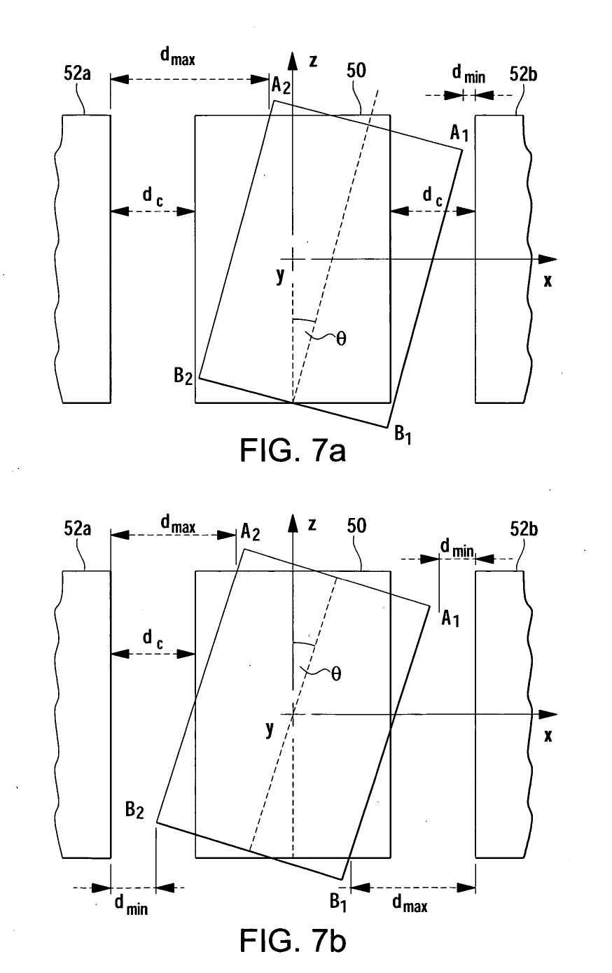

FIGS. 7a and 7b are simple geometric illustrations of the virtual feel concept wherein plate 50 is rotated. FIG. 7a shows plate 50 and parallel plates 52a and 52b wherein plate 50 is rotated some angle θ about the bottom center of plate 50. This case is analogous to rotating about a tool tip center. Whenever plate 50 is moved (translation or rotation) from center, capacitance increases and whenever capacitance increases, the signal displacement current increases and can be measured. Rotating plate 50 some angle θ as shown in FIG. 7a causes a point A1 on the plate surface to move to within d_{MIN}(or very close) and a corresponding point A2 on the opposite surface to move away to d_{MAX}(relatively far away). For the point pair (A1, A2), capacitive coupling between plate 50 and ground plate 52b increases over the centered condition. When considering the corresponding point pairs (A1, A21) of FIGS. 7a and 7b, we see that for each pair, one point is moved closer to ground and its counter point is moved further away, resulting in a net increase in capacitive coupling. The further away a point pair is from the center of rotation, the greater the capacitive coupling; the closer a point pair is to the center of rotation, the less the coupling. The same effect typically occurs whether the angle of rotation is clockwise or counter clockwise. For conductive materials, the charge (and displacement current) can concentrate in the vicinity of d_{MIN} and the charge (and displacement current) can be less in the vicinity of d_{MAX}. So when contact clearances get very small, displacement current (and our ability to sense pre contact) can be large, even when the area in the immediate vicinity of contact is relatively small (as for the case of rotation). Rotation misalignments may be easily sensed; but rotation sensing may not be as sensitive as translation perturbations because translation affects a larger surface area.

In FIG. 7b, plate 50 is rotated about the plate center. This case may be analogous to rotating about the center of a tool shank. This case is similar to the rotation scenario shown in FIG. 7a, but in this case there are two (2) minimum separation gaps (d_{MIN}) rather than one (1), and the slope is twice as steep. Consequently, there may be less surface area in the regions of near contact. Computer modeling/analysis can determine the actual performance in each case.

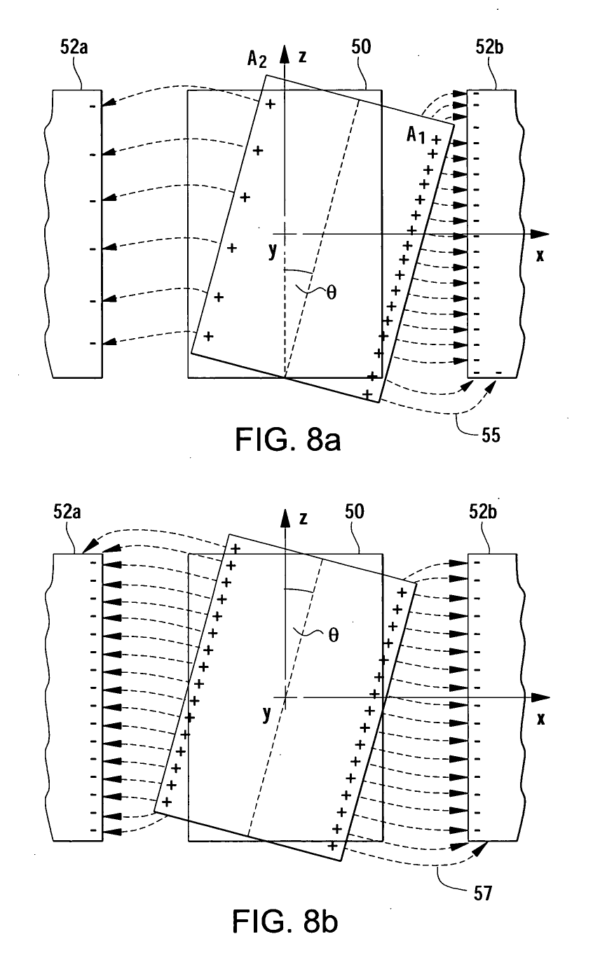

FIG. 8a shows an embodiment of a rotated electrode plate 50 with charge distribution lines 55 between parallel plates 52a and 52b. When the electrode plate 50 is rotated about the tool point (bottom center of plate 50) there is movement of a point pair (A1, A2) away from minimum, centered, capacitance and a net gain in charge and displacement current. The charge distribution lines 55 illustrate the fact that capacitance is increased at point A1 which corresponds to d_{MIN} illustrated in FIG. 7a.

FIG. 8b shows rotated electrode plate 50 with charge distribution lines 57 between parallel plates 52a and 52b. FIG. 8b shows charge distribution between parallel plates when plate 50 is rotated about the tool center. The charge distribution lines illustrate an increased capacitance at the both points A1 and B2, which correspond to d_{MIN} illustrated in FIG. 7b.

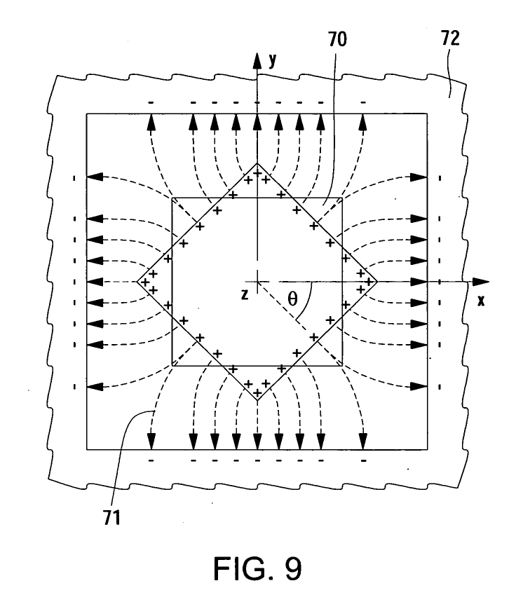

FIG. 9 shows charge distribution in 3-D rotation about the Z-axis using top view of an embodiment with electrode plate 70 inside a larger square grounded channel 72 with charge distribution lines 71. Charge distribution lines 71 illustrate the areas of increased capacitance between plate 70 and channel 72.

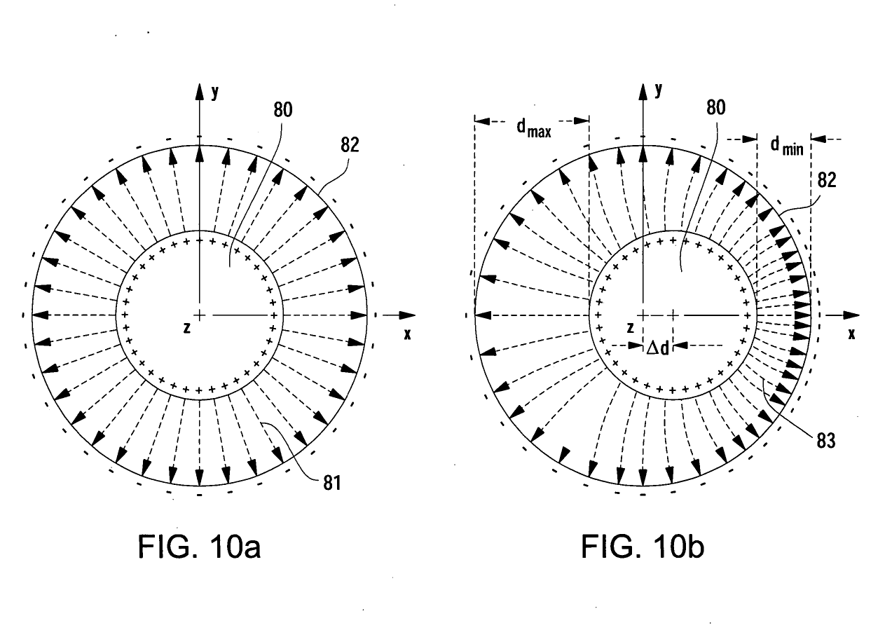

FIGS. 10a and 10b show a top view of charge distribution in 3-D translation for an embodiment with a round rod 80 inside a round cylinder 82. FIG. 10a shows charge distribution lines 81 are minimum when the rod 80 and cylinder 82 are concentric. FIG. 10b illustrates that the charge distribution 83 increases when the rod 80 is translated towards the cylinder 82.

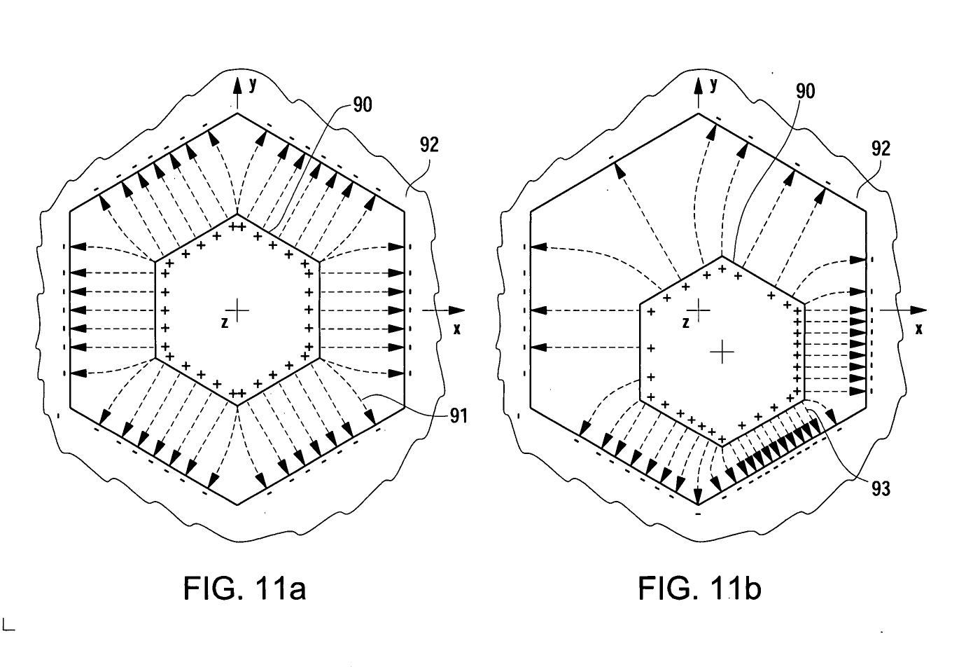

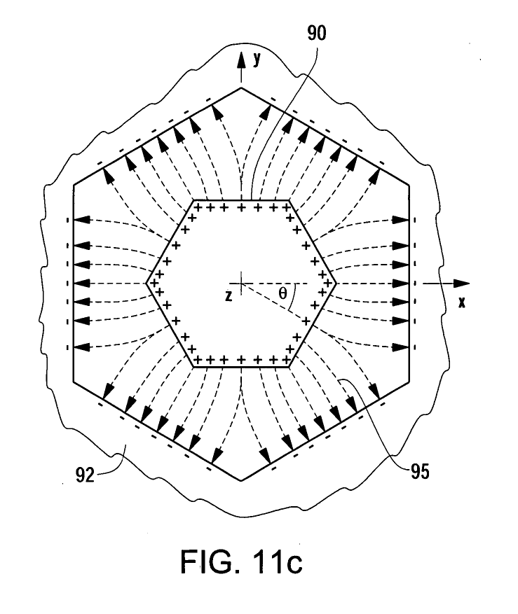

FIGS. 11a and 11c show an embodiment with a hexagonal plate 90 and the associated charge distributions. The results are similar to what has been experienced in the other configurations. FIG. 11a shows charge distribution 91 for plate 90 when the tool is centered with respect to a hexagonal shape channel 92. FIG. 11b shows the charge distribution 93 for plate 90 when it moves in translation. FIG. 11c simply shows the hexagonal plate 90 rotated some angle θ with the associated charge distribution 95.

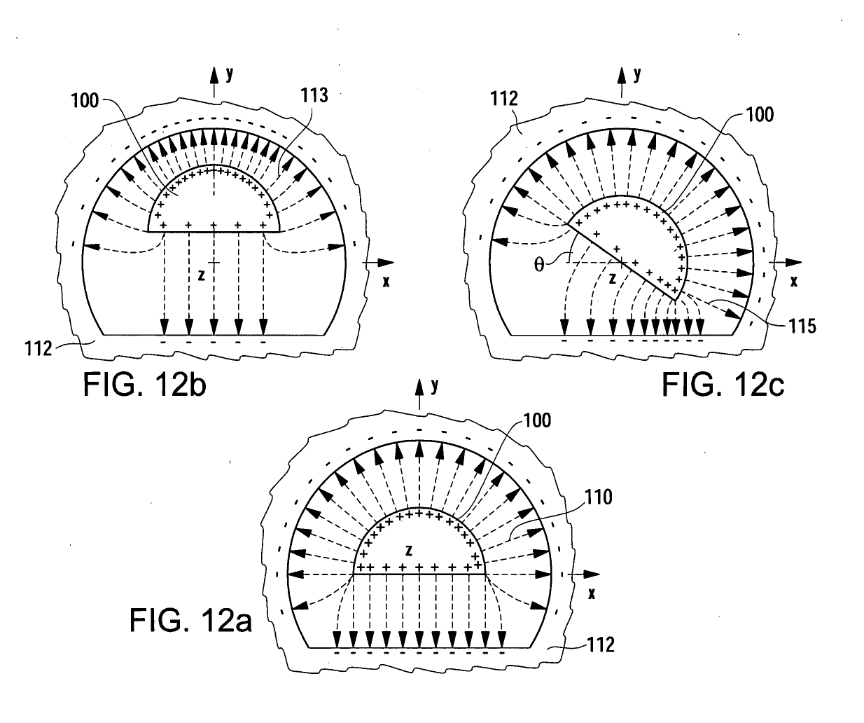

FIGS. 12a and 12c show an embodiment with an asymmetric plate 100 and the associated charge distributions. The results are similar to what has been experienced in the other configurations. FIG. 13a shows charge distribution 110 for plate 100 when the tool is centered with respect to similarly shaped asymmetric channel 112. FIG. 13b shows the charge distribution 113 for plate 100 when it moves in translation. FIG. 13c simply shows the asymmetric plate 100 rotated some angle θ with the associated charge distribution 115.

To those skilled in the art, many modifications and variations of the present invention are possible in light of the teachings contained herein. It is therefore to be understood that the present invention can be practiced otherwise than as specifically describe by these teachings and still be within the spirit and scope of the claims.

1. A capacitive proximity sensing device comprising:
a single inner electrically conductive element;
a single outer electrically conductive element;
an insulation film located between said inner electrically conductive element and said outer electrically conductive element; and,
a sensing element with a six degree-of-freedom capacitive sensing capability wherein said sensing element is integrally formed with said inner and said outer electrically conductive elements.

2. A capacitive proximity sensing device according to claim 1 wherein the single inner electrically conductive element is a Capaciflector electrode.

3. A capacitive proximity sensing device according to claim 1 wherein the single outer electrically conductive element is a Capaciflector electrode.

4. A capacitive proximity sensing device according to claim 3 wherein said Capaciflector electrode includes an electrode contact surface.

5. A capacitive proximity sensing device according to claim 4 wherein said contact surface and said sensing element are one in the same.

6. A capacitive proximity sensing device according to claim 1 wherein said sensing element provides six degree-of-freedom sensing information in response to an adjustment in movement of said sensing element.

7. A capacitive proximity sensing device according to claim 6 wherein said movement is a translational movement.

8. A capacitive proximity sensing device according to claim 6 wherein said movement is a rotational movement.

9. A capacitive proximity sensing device according to claim 1 wherein said outer electrically conductive element also functions as a shield from electric charge distribution from undesired objects.

10. A capacitive proximity sensing device according to claim 1 wherein said sensing element is of a complex shape.

11. A capacitive proximity sensing device according to claim 1 wherein said sensing element is an end-effector.

12. A capacitive proximity sensing device according to claim 1 wherein said sensing element is a socket wrench head.

13. Amended) A system for capacitive proximity sensing comprising:
a single inner Capaciflector electrode;
a single outer Capaciflector electrode;
an insulation film located between said inner Capaciflector electrode and said outer Capaciflector electrode; and,
an end-effector with a for sensing capacitance in six degrees degree-of-freedom capacitance sensing capability wherein said end-effector is connected to said inner and said outer Capaciflector electrodes.

14. (canceled)

15. A system according to claim 13 wherein said single outer Capaciflector electrode provides six degree-of-freedom sensing information in response to an adjustment in movement of said end-effector.

16. A system according to claim 15 wherein said movement of said end-effector is a translational movement.

17. A system according to claim 15 wherein said movement of said end-effector is a rotational movement.

18. A system according to claim 13 wherein said outer Capaciflector electrode also functions as a shield from electric charge distribution from undesired objects.

19. A system according to claim 13 wherein said capacitance increases as a surface on said Capaciflector electrode approaches a surface of an object.

20. A system according to claim 13 wherein said capacitance decreases as a surface on said Capaciflector electrode moves away from a surface of an object.

21. A system according to claim 20 wherein said capacitance increase results in an increase in a net displacement charge.

22. A system according to claim 20 wherein said single outer Capaciflecttor Capaciflector electrode can sense, precisely position and align with respect to said surface of said object.

23. A system according to claim 23 22 wherein said positioning and aligning are performed in a manner analogous to human feelin reaction to a change in a distance between said Capaciflector electrode and said object.

24. A system according to claim 24 22 wherein said positioning and aligning are performed by moving along a preferred direction while adjusting the tool to minimize proximity to side contacts.

25. A proximity sensing device comprising:
a single inner Capaciflector electrode;
a single outer Capaciflector electrode wherein said inner and outer Capaciflector electrodes are coaxially positioned;
an insulation film located between said inner Capaciflector electrode and said outer Capaciflector electrode; and,
an end-effector with a for sensing capacitance in six degrees degree-of-freedom capacitance sensing capability wherein said end-effector is connected to said inner and said outer Capaciflector electrodes.
